(19) United States
(12) Patent Application Publication
(10) Pub. No.: US 2008/0210992 A1
(43) Pub. Date: Sep. 4, 2008

(54) CMOS IMAGE SENSOR AND METHOD OF MANUFACTURING THE SAME

(76) Inventor: Tae-Gyu Kim, Gyeongsangnam-do (KR)

Correspondence Address: SHERR & NOURSE, PLLC, 620 HERNDON PARKWAY, SUITE 200, HERNDON, VA, 20170, US

(21) Appl. No.: 11/964,456

(22) Filed: Dec. 26, 2007

(30) Foreign Application Priority Data
Dec. 29, 2006 (KR) 10-2006-0137341

(51) Int. Cl. H01L 31/062; H01L 21/00

(52) U.S. Cl. 257/292; 438/60; 257/E31.001; 257/E21.001

(57) ABSTRACT

A CMOS image sensor that can include a first shallow trench isolation layer and a second shallow trench isolation layer formed in an epitaxial layer on both sides of a predetermined region of the epitaxial layer; a poly gate contacting the first shallow trench isolation layer and the second shallow trench isolation layer and formed over the predetermined region of the epitaxial layer; and a plurality of channels formed in the epitaxial layer and under the poly gate.

This application claims the benefit of Korean Patent Application No. 10-2006-0137341 (filed on Dec. 29, 2006), which is hereby incorporated by reference in its entirety.

### BACKGROUND

An image sensor is a device that converts an optical image into an electrical signal. The image sensor may be classified as a complementary metal-oxide-silicon (CMOS) image sensor and a charge coupled device (CCD) image sensor.

The CCD image sensor is excellent in characteristics for photo sensitivity and noise reduction. Achieving high integration in CCD image sensors may be difficult, and the CCD image sensor also has a high rate of power consumption. The CMOS image sensor, on the other hand, may be manufactured using simple process steps, and may be suitable where high integration and low power consumption is required.

A pixel of a CMOS image sensor may include a plurality if photodiodes receiving light and a plurality of transistors controlling image signals input from the photodiodes. The CMOS image sensor can be classified in terms of the number of transistors (T), such as a 3T-type and a four T-type. A 3T-type may include one photodiode and three transistors while a 4T-type may include one photodiode and four transistors.

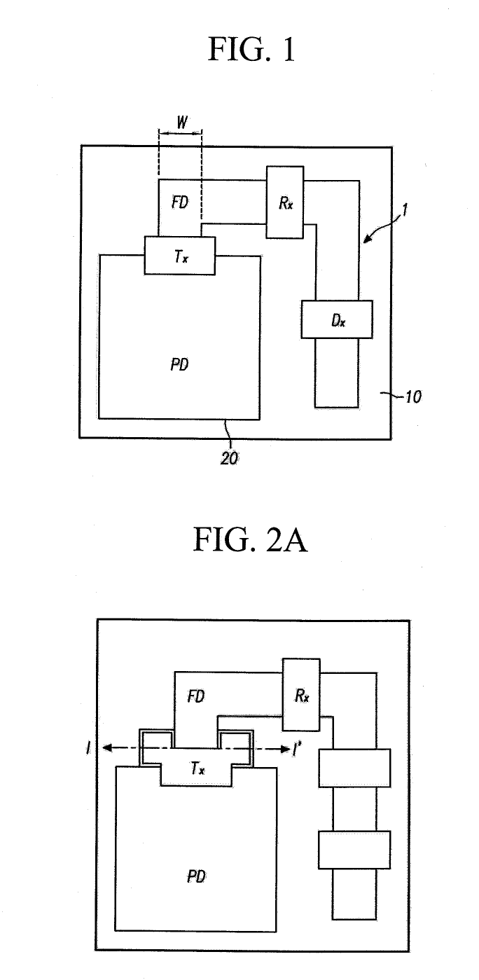

As illustrated in example FIG. 1, a CMOS image sensor may include device isolating layer 10 isolating active region 1 and a device isolating region of a semiconductor substrate, photodiode region PD formed in lattermost area in active region 1 for sensing incident light and generating charges in accordance with the quantity of light, transfer transistor (Tx) overlapping active region 1 except photodiode region (PD) to transfer charges generated from photodiode (PD) to floating diffusion region (FD), reset transistor (Rx), and drive transistor (Dx).

Before transfer transistor (Tx) transfers charges generated from photodiode (PD) to floating diffusion region (FD), floating diffusion region (FD) moves electrons from photodiode (PD) to reset transistor (Rx) to turn on the reset transistor (Rx) so that floating diffusion region (FD) may be set in a predetermined low charge state. Reset transistor (Rx) may serve to discharge charges stored in floating diffusion region (FD) in order to detect a signal. Drive transistor (Dx) may serve as a source follower converting the charges into a voltage signal.

In order to obtain high integration, photodiode region (PD) and the pixel area may be reduced, and the overall width of transfer transistor (Tx) may be reduced so that the channel width of transfer transistor (Tx) is also reduced. Thus, there is a limitation in totally transferring electrons from photodiode region (PD) to floating diffusion region (FD).

The problem of such a fine difference has an effect on real saturation current. Meaning, the width of transfer transistor (Tx) may be reduced to delay time required for the saturation current to be output, thereby making it possible to deteriorate image characteristic.

### SUMMARY

Embodiments relate to a method of manufacturing a CMOS image sensor that can prevent the delay of output time of saturation current due to the reduction of the width of a transfer transistor (Tx).

Embodiments relate to a CMOS image sensor having a rapid saturation current output characteristic and which may also improve an image characteristic by enlarging the total channel width of transfer transistor (Tx).

Embodiments relate to relate to a CMOS image sensor that can include at least one of the following: an epitaxial layer formed over a semiconductor substrate; a first shallow trench isolation and a second shallow trench isolation formed in an epitaxial layer on both sides of the region of the epitaxial layer; a poly gate contacting the first shallow trench isolation and the second shallow trench isolation and formed over the region of the epitaxial layer; and a plurality of channels formed in the epitaxial layer and under the poly gate.

Embodiments relate to relate to a method of manufacturing a CMOS image sensor that can include at least one of the following steps: forming a first channel and a second channel in a predetermined region of an epitaxial layer; forming a first shallow trench isolation layer and a second shallow trench isolation layer in an epitaxial layer on both sides of the predetermined region of the epitaxial layer; forming a first trench adjacent a first side of the predetermined region in the first shallow trench isolation layer and a second trench adjacent a second side of the predetermined region in the second shallow trench isolation layer; forming a pair of oxide films in the first and second trenches of the shallow trench isolation layers; forming a conductive film over each oxide film; forming a third channel in the predetermined region and extending substantially perpendicular relative to the first and second channels while also interconnecting the first and second channels; forming a gate oxide film over the predetermined region interconnecting the oxide films; and then forming a poly gate over the predetermined region of the epitaxial layer and each conductive film.

Embodiments relate to relate to a method of manufacturing a CMOS image sensor that can include at least one of the following steps: forming a first plurality of trenches in an epitaxial layer; forming a first channel and a second channel in a predetermined region of the epitaxial layer; forming an oxide film in each one of the first plurality of trenches; forming a conductive film over the oxide film; forming a pair of device isolating layers by gap filling a silicon oxide film in each one of the second plurality of trenches using a CMP process; forming a third channel in the predetermined region and extending substantially perpendicular relative to the first and second channels while also interconnecting the first and second channels; forming a gate oxide film over the predetermined region interconnecting the oxide films; forming a poly gate over the conductive film and the gate oxide film.

### DRAWINGS

Example FIG. 1 illustrates a CMOS image sensor.

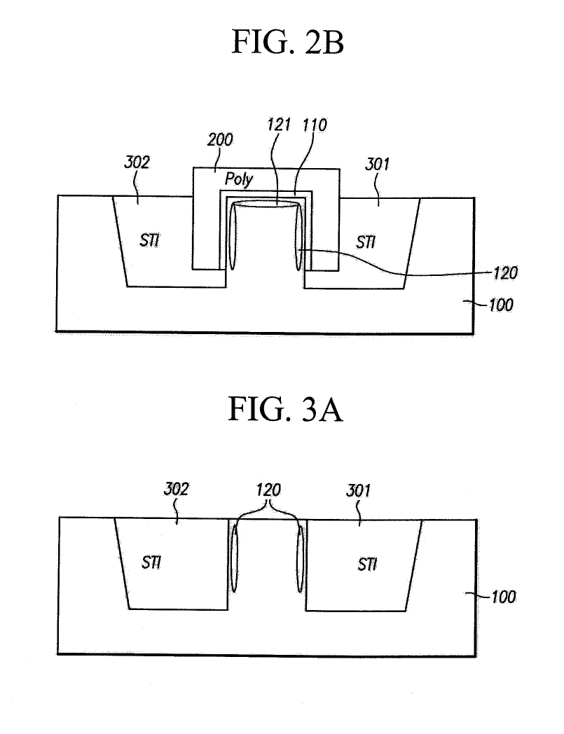

Example FIG. 2 to 4 illustrates a CMOS image sensor, in accordance with embodiments.

### DESCRIPTION

As illustrated in example FIGS. 2A and 2B, a CMOS image sensor in accordance with embodiments can include transfer transistor (Tx) having an overall wide width. Accordingly, first and second shallow trench isolations (STIs) 301, 302 can be formed in P-type epitaxial layer 100 on both sides of the gate of transfer transistor (Tx). STIs 301, 302 can be formed with poly gate 200 connected to the gate of transfer transistor (Tx).

Side channel 120 can be formed in epitaxial layer 100, under poly gate 200 and adjacent STIs 301, 302. In order to control gate voltage, horizontal channel 121 connected each side channel 120 can be formed under poly gate 200 by implanting a dopant. Accordingly, a path through which electrons can be moved becomes wider as opposed to forming horizontal channel 121 so that all of the electrons can rapidly be transferred to floating diffusion region (FD), thereby making it possible to further rapidly and perfectly obtain saturation current.

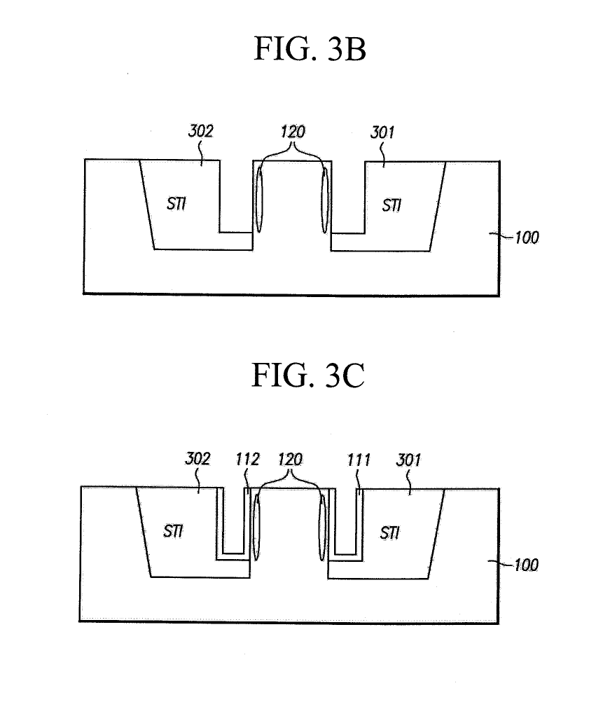

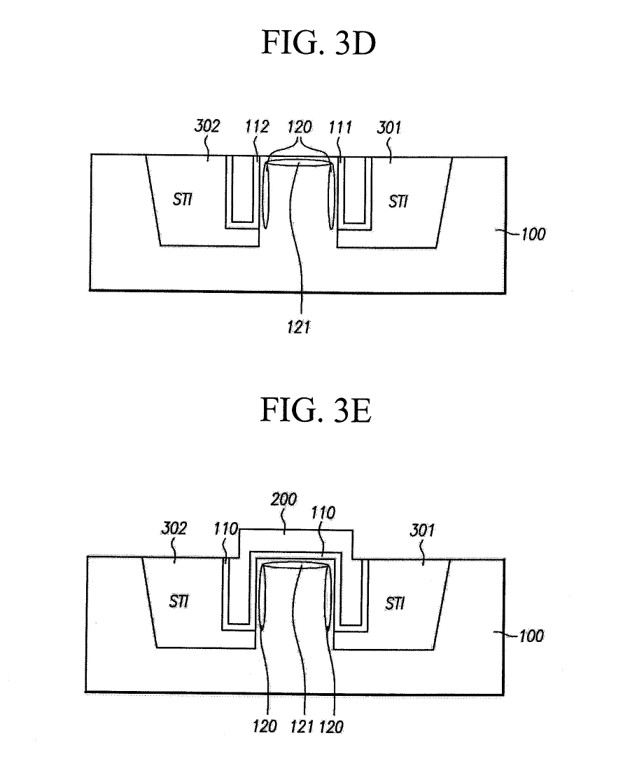

Example FIGS. 3A to 3E illustrate a method of manufacturing the CMOS image sensor in accordance with embodiments, particularly, a manufacturing process with respect to transfer transistor (Tx) region of the CMOS image sensor.

As illustrated in example FIG. 3, low-concentration P-type epitaxial layer 100 can be formed by performing an epitaxial process on and/or over a semiconductor substrate.

A plurality of trenches can then be formed in P-type epitaxial layer 100 using an STI process. Side channels 120 can be formed by implanting dopant between the trenches of P-type epitaxial layer 100, particularly, at a region where poly gate 200 will be subsequently formed. First and second device isolating layers 301, 302 can then be formed by gap filling a silicon oxide film in each of the trenches.

As illustrated in example FIG. 3B, a first photo resist pattern can then be formed on and/or over respective device isolating layers 301, 302 to form poly gate 200. Trenches can then be formed in respective device isolating layers 301, 302 adjacent each side channel 120 by performing an etching using the first photo resist pattern as a mask.

As illustrated in example FIG. 3C, liner oxide films 111, 112 configured in a U-shape having a trench therein can then be formed in each trenches of device isolating layers 301, 302.

As illustrated in example FIG. 3D, after forming liner oxide films 111, 112, a conductive film can then be formed by gap filling poly silicon or an electrical conductive material in each trench of liner oxide films 111, 112. A CMP process can then be performed to planarize the overall surface of the P-type epitaxial layer 100 including the conductive film. Horizontal channel 121 interconnecting side channels 120 can then be formed by implanting dopants adjacent side channels 120 in the uppermost surface of planarized P type epitaxial layer 100. Particularly, horizontal channel 121 can be formed by implanting the dopant into the uppermost surface of epitaxial layer 100 where the gate of transfer transistor (Tx) will be formed, i.e., between the trenches formed in device isolating layers 301 and 302.

As illustrated in example FIG. 3E, gate oxide film 110 interconnecting liner oxide films 111, 112 can then be formed on and/or over the planarized P-type epitaxial layer 100 by forming a second photoresist pattern and depositing a silicon oxide film using the second photoresist as a mask. Gate oxide film 110 can be formed on and/or over epitaxial layer 100 where the gate of transfer transistor (Tx) will be formed. The second photoresist pattern can then be removed by an ashing process.

A polysilicon material can then be deposited on and/or over epitaxial layer 100 including gate oxide film 110 and patterned using a third photoresist pattern exposing a region including gate oxide film 110 in order to form poly gate 200. Poly gate 200 can be formed by depositing a poly silicon material on and/or over epitaxial layer 100 including gate oxide film 100 and a portion of the surfaces of the conductive films by a gap fill.

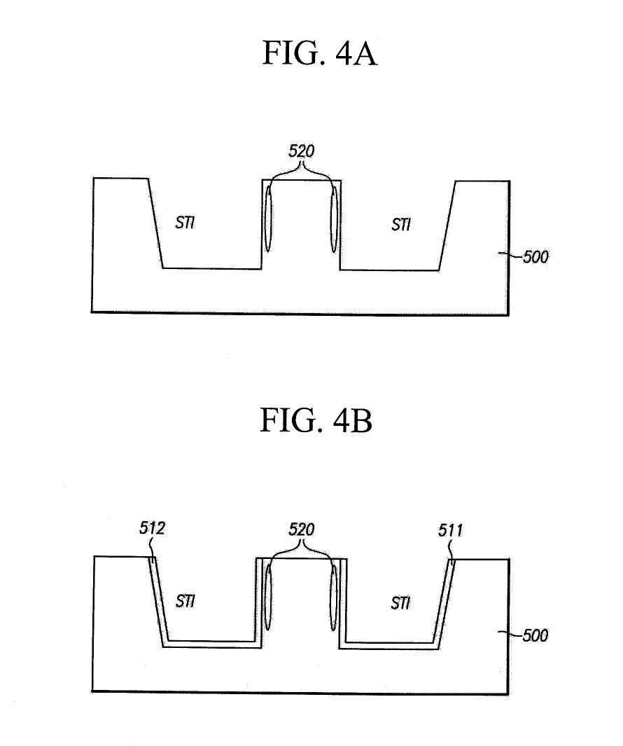

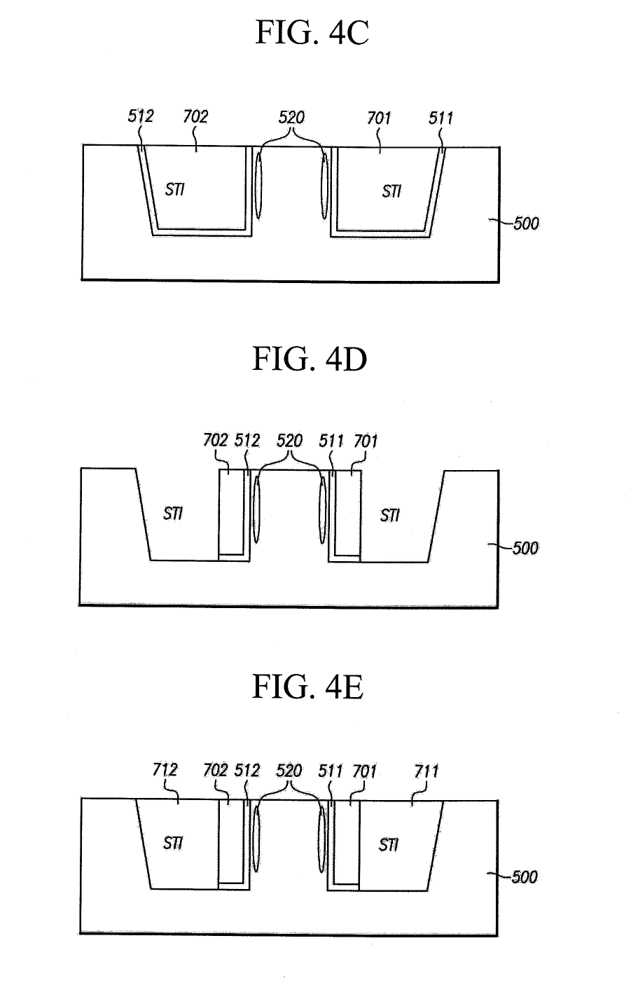

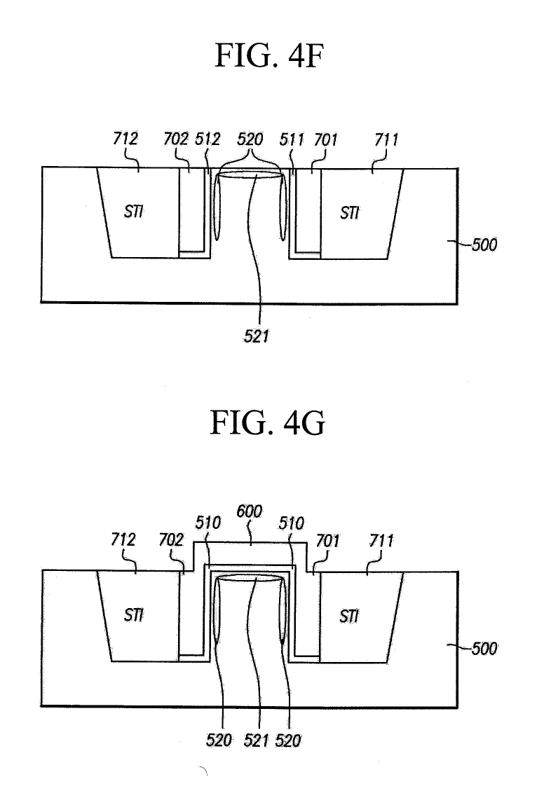

Example FIGS. 4A to 4E illustrate a method of manufacturing the CMOS image sensor in accordance with embodiments, particularly, a manufacturing process with respect to transfer transistor (Tx) region of the CMOS image sensor.

As illustrated in example FIG. 4A, low-concentration P-type epitaxial layer 500 can be formed by performing an epitaxial process on and/or over a semiconductor substrate. A plurality of trenches can then be formed in P-type epitaxial layer 500 by an STI process. Side channels 520 can then be formed by implanting dopants in a region between the trenches of epitaxial layer 500, i.e., in a region where poly gate 600 will be subsequently formed.

As illustrated in example FIGS. 4B and 4C, liner oxide films 511, 512 can then be formed in each trench. Conductive films 701, 702 can then be formed by gap filling poly silicon or an electrical conductive material on and/or over liner oxide films 511, 512. A CMP process can then be performed to planarize the overall surface of P-type epitaxial layer 500.

As illustrated in example FIGS. 4D and 4E, a first photoresist pattern can then be formed on and/or over a region where poly gate 600 will be formed, i.e., P-type epitaxial layer 500 including side channels 520. The first photo resist pattern can be formed on and/or over epitaxial layer 500 between the STI trenches corresponding to a region where poly gate 600 will be formed and a portion of the surfaces of conductive films 701, 702. An etching process can then be performed through the first photo resist pattern to remove at least a portion of conductive films 701, 702 and liner oxide films 511, 512. Accordingly, an inner portion of conductive films 701, 702 that become a portion of poly gate 600 adjacent side channels 520 remains. Thereby, the trenches can be formed laterally away from side channels 520. Planar device isolating layers 711 and 712 can then be formed by gap filling a silicon oxide film in each of the trenches using a CMP process.

As illustrated in example FIG. 4F, horizontal channel 521 can then be formed by implanting dopants into the region of epitaxial layer 500 where side channels 520 are formed. A second photo resist pattern can then be formed on and/or over planarized P-type epitaxial layer 500 by exposing liner oxide films 511, 512 in order to inter-connect liner oxide films 511, 512. A silicon oxide film can then be deposited using the second photo resist pattern to form gate oxide film 510 inter-connecting liner oxide films 511, 512. The second photo resist pattern can then be removed by an ashing process.

As illustrated in example FIG. 4G, a third photo resist pattern exposing the region of conductive films 701, 702 including gate oxide film 510 can then be formed in order to form poly gate 600. A poly silicon material can then be deposited and patterned using the third photo resist pattern to form poly gate 600.

Embodiments can be advantageous by preventing delay in the output time of the saturation current from due to the reduction of width of transfer transistor (Tx).

In accordance with embodiments, gate voltage can be controlled by providing on both sides of the gate of transfer transistor (Tx) an STI including a poly gate connected to the gate of transfer transistor (Tx), and also side channels and a horizontal channel formed under the poly gate. Therefore, a path through which electrons can totally be moved becomes wide so that the electrons can be rapidly transferred from photodiode region (PD) to floating diffusion region (FD), thereby making it possible to further rapidly and perfectly obtain saturation current.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a first shallow trench isolation layer and a second shallow trench isolation layer formed in an epitaxial layer on both sides of a predetermined region of the epitaxial layer;
a poly gate contacting the first shallow trench isolation layer and the second shallow trench isolation layer and formed over the predetermined region of the epitaxial layer; and
a plurality of channels formed in the epitaxial layer and under the poly gate.

2. The apparatus of claim 3, wherein a gate of a transfer transistor formed over the predetermined region of the epitaxial layer;

3. The apparatus of claim 3, wherein the poly gate is connected to the gate of the transfer transistor.

4. The apparatus of claim 3, wherein the poly gate comprises a first poly gate portion contacting the first shallow trench isolation layer, a second poly gate portion contacting the second shallow trench isolation layer, and a third poly gate portion extending substantially perpendicular relative to the first and second poly gate portions and also interconnecting the first and second poly gate portions.

5. The apparatus of claim 4, wherein the third poly gate portion is provided over the predetermined region of the epitaxial layer.

6. The apparatus of claim 5, wherein the plurality of channels comprises a first channel and a second channel formed in opposing sides of the predetermined region of the epitaxial layer, and a third channel extending substantially perpendicular relative to the first and second channels and interconnecting the first and second channels.

7. The apparatus of claim 6, wherein the first channel and the second channel formed extend substantially parallel to the first and second poly gate portions and the third channel extends substantially parallel to the third poly gate portion.

8. The apparatus of claim 1, wherein the plurality of channels comprises a first channel and a second channel formed in opposing sides of the predetermined region of the epitaxial layer, and a third channel extending substantially perpendicular relative to the first and second channels and interconnecting the first and second channels.

9. The apparatus of claim 1, further comprising a gate oxide film provided between the poly gate and the region of the epitaxial layer.

10. The apparatus of claim 1, wherein the poly gate comprises at least one of poly silicon and an electrical conductive material.

11. A method comprising:
forming a first channel and a second channel in a predetermined region of an epitaxial layer;
forming a first shallow trench isolation layer and a second shallow trench isolation layer in an epitaxial layer on both sides of the predetermined region of the epitaxial layer;
forming a first trench adjacent a first side of the predetermined region in the first shallow trench isolation layer and a second trench adjacent a second side of the predetermined region in the second shallow trench isolation layer;
forming a pair of oxide films in the first and second trenches of the shallow trench isolation layers;
forming a conductive film over each oxide film;
forming a third channel in the predetermined region and extending substantially perpendicular relative to the first and second channels while also interconnecting the first and second channels;
forming a gate oxide film over the predetermined region interconnecting the oxide films; and then
forming a poly gate over the predetermined region of the epitaxial layer and each conductive film.

12. The method of claim 11, wherein forming the forming a first shallow trench isolation layer and the second shallow trench isolation layer comprises:
forming a first trench and a second trench in the epitaxial layer using an STI process before forming the first and second channels; and then
gap filling a silicon oxide film in the first and second trenches after forming the first and second channels.

13. The method of claim 11, wherein forming the gate oxide film comprises:
forming a photoresist pattern over the epitaxial layer; and then
depositing a silicon oxide film using the photoresist as a mask.

14. The method of claim 13, wherein the gate oxide film is formed over the predetermined region where a gate of a transfer transistor is formed. The second photoresist pattern can then be removed by an ashing process.

15. A method comprising:
forming a first plurality of trenches in an epitaxial layer;
forming a first channel and a second channel in a predetermined region of the epitaxial layer;
forming an oxide film in each one of the first plurality of trenches;
forming a conductive film over the oxide film;
forming a pair of device isolating layers by gap filling a silicon oxide film in each one of the second plurality of trenches using a CMP process;
forming a third channel in the predetermined region and extending substantially perpendicular relative to the first and second channels while also interconnecting the first and second channels;
forming a gate oxide film over the predetermined region interconnecting the oxide films; and then
forming a poly gate over the conductive film and the gate oxide film.

16. The method of claim 15, wherein the predetermined region of the epitaxial layer is between the first plurality of trenches.

17. The method of claim 15, wherein forming the forming the conductive film comprises:
gap filling at least one of a polysilicon material and an electrical conductive material over the oxide film; and then
planarizing the surface of the epitaxial layer.

18. The method of claim 15, wherein forming the pair of device isolating layers comprises:
forming a first photoresist pattern over the predetermined region;
forming a second plurality of trenches by removing a portion of the conductive film and the oxide film by an etching process using the first photoresist pattern;
gap filling a silicon oxide film in the second plurality of trenches; and then
removing the first photoresist pattern.

19. The method of claim 18, wherein forming the gate oxide film comprises:
exposing the uppermost surface of the oxide films by forming a second photoresist pattern over the epitaxial layer;
depositing a silicon oxide film using the second photoresist pattern; and then
removing the second photoresist pattern.

20. The method of claim 19, wherein forming the poly gate comprises:
exposing the conductive film and the gate oxide film by forming a third photo resist pattern;
depositing a polysilicon material over the conductive film and the gate oxide film and patterning the polysilicon material using the third photoresist pattern; and then
removing the third photoresist pattern.
